(19) United States
(12) Patent Application Publication
(10) Pub. No.: US 2010/0252098 A1
(43) Pub. Date: Oct. 7, 2010

(54) Cord Plate Attachment to Photovoltaic Modules

(76) Inventors: Brian E. Cohen, Perrysburg, OH (US); Branden Michael Robinson Welch, Bowling Green, OH (US); Bruce H. Bengtson, Perrysburg, OH (US); Lindsay A. Horn, Perrysburg, OH (US)

Correspondence Address: STEPTOE & JOHNSON LLP, 1330 CONNECTICUT AVENUE, N.W., WASHINGTON, DC, 20036, US

(21) Appl. No.: 12/720,444

(22) Filed: Mar. 9, 2010

Related U.S. Application Data
(60) Provisional application No. 61/159,504, filed on Mar. 12, 2009.
(60) Provisional application No. 61/236,379, filed on Aug. 24, 2009.

(51) Int. Cl. H01L 31/00; C09J 5/10

(52) U.S. Cl. 136/256; 156/306.9

(57) ABSTRACT

A method of attaching a cord plate to a photovoltaic module is disclosed. The photovoltaic module has a cover plate.

### CLAIM OF PRIORITY

This application claims priority to U.S. Provisional Patent Application No. 61/159,504, filed on Mar. 12, 2009 and U.S. Provisional Patent Application No. 61/236,379, filed on Aug. 24, 2009, which are incorporated by reference in their entirety.

### TECHNICAL FIELD

This invention relates to a method of attaching a cord plate to a photovoltaic module.

### BACKGROUND

One challenge in solar energy industry has been to develop a way to attach the cord plate to a photovoltaic module not only securely, but also quickly. Another challenge has been to maintain excellent adhesion between the cord plate and the photovoltaic module after being exposed to varying environmental factors, such as temperature, humidity, sun exposure, or combinations thereof.

### DESCRIPTION OF DRAWINGS

FIG. 1 is a perspective view illustrating a cord plate, a cover plate of a photovoltaic module, and an adhesive in separate position.

FIG. 2 is a perspective view illustrating a cord plate positioned on a cover plate of a photovoltaic module with an adhesive placed between the cord plate and the cover plate for short-term adhesion.

FIG. 3 is a perspective view illustrating the cord plate positioned on a cover plate of a photovoltaic module with filling a sealant to flow down from a channel of the cord plate and filling the hole of the cover plate.

### DETAILED DESCRIPTION

To attach the cord plate to the photovoltaic module and maintain excellent adhesion, a new method has been developed that permits positioning a cord plate on a surface of a photovoltaic module cover plate and introducing a sealant into the cord plate. The sealant flows through the cord plate and contacts the cord plate and the cover plate, eventually curing to form a robust adhesive bond between the cord plate and the photovoltaic module. An acrylic foam sheet, which can be primed with a primer, can be positioned between the bottom surface of the cord plate and the top or first surface of the cover plate.

In one aspect, a method of attaching a cord plate to a photovoltaic module having a cover plate may include positioning a conductor adjacent to a cover plate of a photovoltaic device, positioning the cord plate on the first surface of the cover plate over the connector to form a space defined by the cover plate, the connector, and the cord plate, and positioning an acrylic foam sheet between the bottom surface of the cord plate and the first surface of the cover plate. The conductor can include a first end configured to be connected to the photovoltaic device and a second end located proximate to a connector on a first surface of the cover plate. The cord plate can include a base having a top surface and bottom surface and configured to be sealed to the cover plate, a junction configured to intersect the conductor and a second conductor, and a channel configured to receive a flowable sealant.

The method can further include the steps of introducing a flowable sealant into the cord plate channel, causing the flowable sealant to flow into the defined space and contact the channel, the cover plate and the connector, and curing the flowable sealant to connect the cord plate to the cover plate. The cover plate may include glass. The connector may include an impression formed in the first surface of the cover plate. The connector can include a hole formed through the cover plate. The conductor may include a foil strip. The cord plate may include plastic. The cord plate may include polycarbonate. The base may include a rectangular plate. The base may include a recess formed in the bottom surface. The junction may include a receptacle formed on the top surface of the base and configured to position the second conductor in contact with the conductor.

The method can further include electrically connecting the conductor and second conductor. The channel may include an opening in the base. The method can further include the step of milling an opening in the base of the channel. The channel may include a partition extending perpendicular from a surface of the base and encircling the opening. The second conductor may include insulated electrical wiring configured to carry electrons either to or from the conductor. The flowable sealant may include a silicone. The flowable sealant may include an acrylic, a polysulfide, a butyl polymer, or a polyurethane.

The method can further include the step of priming the bottom surface of the base before positioning on the cover plate. The bottom surface of the base can be primed with a liquid primer. The bottom surface of the base can be primed with flame treatment. The method can further include the step of positioning a seal on the first surface of the cover plate over the connector before positioning the cord plate on the first surface of the cover plate over the connector. The seal may include an acrylic foam core. The seal may include a pressure sensitive adhesive on a surface of the acrylic foam core.

The method can further include the step of contacting a primer to the bottom surface of the cord plate before positioning the acrylic foam sheet between the bottom surface of the cord plate and the first surface of the cover plate. The method can further include the step of contacting a primer to the first surface of the cover plate before positioning the acrylic foam sheet between the bottom surface of the cord plate and the first surface of the cover plate. The method can further include the step of contacting a primer to the acrylic foam sheet before positioning the acrylic foam sheet between the bottom surface of the cord plate and the first surface of the cover plate. The primer may include a water-based primer. The primer may include a compound which fluoresces when ultraviolet light is directed at the compound. The primer may include an adhesive material.

The step of contacting a primer to the acrylic foam sheet may include brushing primer onto the acrylic foam sheet. The step of contacting a primer to the acrylic foam sheet may include rolling primer onto the acrylic foam sheet. The step of contacting a primer to the acrylic foam sheet may include spraying primer onto the acrylic foam sheet. The step of contacting a primer to the acrylic foam sheet may include silk screening primer onto the acrylic foam sheet. The step of contacting a primer to the acrylic foam sheet may include daubing primer onto the acrylic foam sheet. The step of contacting a primer to the acrylic foam sheet may include placing about 5 grams to about 50 grams of primer onto the acrylic foam sheet. The step of contacting a primer to the acrylic foam sheet may include placing about 10 grams to about 30 grams of primer onto the acrylic foam sheet. The step of contacting a primer to the acrylic foam sheet may include placing about 20 grams of primer onto the acrylic foam sheet. The step of contacting a primer to the acrylic foam sheet may include placing multiple coats of primer onto the acrylic foam sheet. The step of contacting a primer to the acrylic foam sheet may include placing about 3 coats of primer onto the acrylic foam sheet.

In one aspect, a photovoltaic module may include a photovoltaic device, a cover plate positioned adjacent to the photovoltaic device, wherein the cover plate can include a connector formed on a first surface of the cover plate, a conductor including a first end connected to the photovoltaic device and a second end located proximate to the connector, a cord plate including a base including a top surface and bottom surface and configured to be sealed to the cover plate, a junction configured to intersect the conductor and a second conductor, and a channel configured to receive a flowable sealant, wherein the cord plate is positioned on the first surface of the cover plate, over the connector, to form a space defined by the cover plate, the connector and the cord plate, and an acrylic foam sheet positioned between the bottom surface of the cord place and the first surface of the cover plate.

The photovoltaic module can further include a sealant introduced into the cord plate channel, the sealant contacting the channel, the cover plate and the connector. The photovoltaic module can further include a primer contacting the acrylic foam sheet. The primer may include a water based primer. The primer may include a compound which fluoresces when ultraviolet light is directed at the compound. The photovoltaic module can further include a pressure sensitive adhesive on a surface of the acrylic foam sheet.

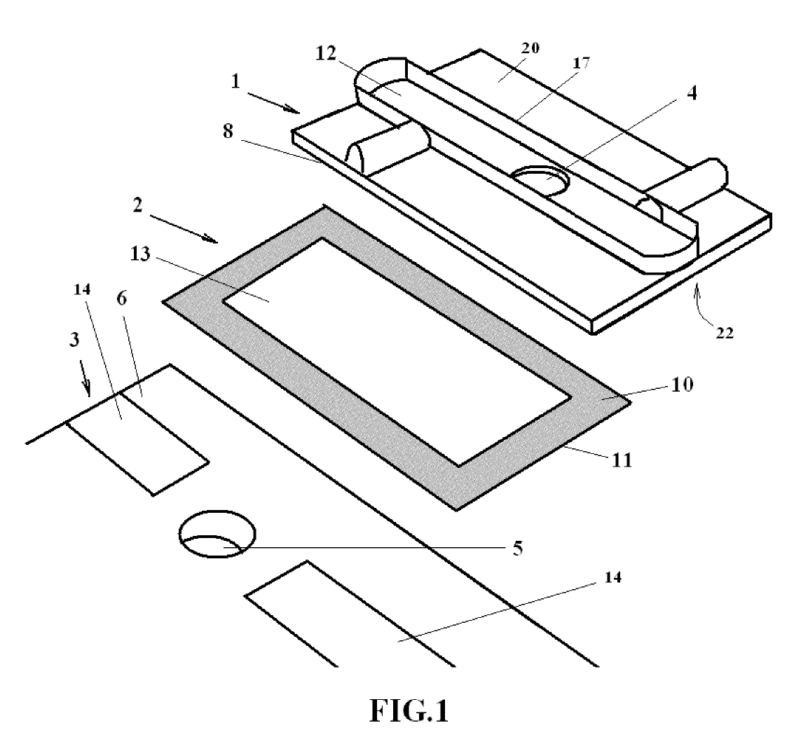

Referring to FIG. 1, cover plate 3 has first surface 6. Cover plate 3 can be configured to be integrated into a photovoltaic module adjacent to one or more photovoltaic devices (not shown). Cover plate 3 can be made of any suitable material, for example, a metal, plastic or glass such as soda-lime glass. Cover plate 3 can include a connector 5. Connector 5 can be any suitable connector, such as a hole formed in cover plate 3. Connector 5 can be an impression formed in first surface 6 of cover plate 3. Connector 5 can be connected to the photovoltaic device of the photovoltaic module.

Conductor 14 can be adjacent to first surface 6 of cover plate 3. For example, conductor 14 can be a foil strip positioned substantially in the plane of first surface 6. Conductor 14 can be a lead foil strip. Conductor 14 can include a first end (not shown) connected to a photovoltaic devices provided on the photovoltaic module. There can be multiple conductors 14. Conductor 14 can include a second end positioned on first surface 6 of cover plate 3. The second end of connector 14 can be positioned proximate to connector 5.

In continuing reference to FIG. 1, cord plate 1 includes a base 8. Base 8 can be rectangular or any other shape suitable for positioning and sealing cord plate 1 adjacent to first surface 6 of cover plate 3. Base 8 can include a top surface 20 and a bottom surface 22, which can be formed as suitable to cooperate and adhere to first surface 6 of cover plate 3. For example, bottom surface 22 of base 8 can be flat. Bottom surface 22 of base 8 can be recessed. Bottom surface 22 of base 8 can form the bottom surface of cord plate 1. To promote adhesion, bottom surface 22 can be primed by preparing the first surface of cord plate with flame treatment, abrasion, or solvent preparation. For example, bottom surface 22 of base 8 can be primed with an organo-silane primer, or any other suitable primer.

Cord plate 1 includes channel 4, which can be an opening formed in base 8, i.e., an opening from top surface 20 to bottom surface 22. Channel 4 is configured to receive a flowable sealant. Channel 4 can be an opening formed by milling a hole through base 8 of cord plate 1. Channel 4 can also be formed by injection molding. Channel 4 can also include partition 17 extending from top surface 20 of base 8. Partition 17 can encircle the hole in base 8 to define a compartment 12 into which a flowable sealant can be received. Cord plate 1 can be any suitable material, including any suitable plastic or polycarbonate, such as LEXAN500. Cord plate 1 can be any suitable color, and can be transparent.

As shown in FIG. 1, cord plate 1 can be positioned proximate to cover plate 3 in preparation for adhering bottom surface 22 of cord plate 1 to first surface 6 of cover plate 3. In this manner, cord plate 1 can be moved into a position adjacent to and in contact with first surface 6 of cover plate 3. Alternatively, seal 2 can be positioned between first surface 6 of cover plate 3 and bottom surface 22 of cord plate 1. Seal 2 can position and adhere cord plate 1 in preparation for a robust, installation-caliber seal. Seal 2 can include a very high bond (VHB) material, including an acrylic foam, for example an acrylic foam sheet 11. Acrylic foam sheet 11 can be in the form of seal 2, or any other suitable form, such as a tape strip. Acrylic foam sheet 11 can include any suitable acrylic foam material, including, for example an acrylic foam tape such as 3M VHB Acrylic Foam Tape (product number 5952). Seal 2 formed from acrylic foam sheet 11 can have an opening 13 that allows channel 4 to be positioned over and in fluid communication with connector 5. Seal 2 can include an adhesive, such as a pressure sensitive adhesive (PSA) applied to a surface of seal 2 that will contact first surface 6 of cover plate 3, bottom surface 22 of cord plate 1, or both. Seal 2 can be shaped substantially similarly to base 8 of cord plate 1. For example, seal 2 can be a rectangle.

Before seal 2 is used to adhere bottom surface 22 of cord plate 1 to cover plate 3, one or more contact surfaces can be primed or otherwise treated to improve adhesion. A flame treatment applied to bottom surface 22 can alter the surface energy or wettability of bottom surface 22 and can increase adhesion. Treatment with a primer or a primer/flame treatment combination can also alter the surface energy or wettability of bottom surface 22 and can increase adhesion. In some embodiments, the primer can include a liquid primer used for low surface energy material. Since the formulations and surface energies can vary for different types of cord plate materials, each application can be verified through testing. In some embodiments, the primer or adhesion promoter can be specifically formulated to be used with seal 2. A surface preparation step can be included before applying the primer. The bonding portion of bottom surface 22 can be clean and dry. Contaminated surfaces can be cleaned with an untreated, lint-free cloth and general purpose adhesive cleaner. The following step can be wiping with another untreated, lint-free cloth and isopropyl alcohol. In some embodiments, treatment with a primer or a primer/flame treatment combination can include applying a thin, uniform coating of primer to the bonding portion of bottom surface 22. When a liquid primer is used, a wet coating thickness can be 0.002 inch or less. The primer can be applied only to areas that will be fully covered with seal 2. Although drying times may vary due to temperature and/or humidity, the drying time can be in the range of 30 to 90 seconds. The primer can be dry before applying seal 2. Seal 2 can be applied immediately after primer application or no more than one hour after primer application. The primer can be applied with a dauber, brush, roller, spray, silk screen, or any other suitable tool. The surface treatment can also include surface etching, mechanical abrasion, or any other suitable process.

In some embodiments, an adhesion promoter or primer can be used to alter the surface characteristics of bottom surface 22 of base 8 prior to the application of seal 2. This surface alteration can enhance or create a modified surface for bonding with a particular pressure sensitive adhesive. Adhesion promoter or primer can be used to raise the substrate surface energy of low surface energy material, allowing for increased short and long-term adhesion levels of acrylic foam tape adhesives. In some embodiments, bottom surface 22 of cord plate 1 can be primed with a water-based primer. Bottom surface 22 of cord plate 1 can be primed with a ultraviolet-fluorescent primer containing a compound which fluoresces when ultraviolet light is directed at the compound. The primer can include 3M Adhesion Promoter (product number 4298). The primer can be applied in multiple layers, for example, in three layers, before seal 2 is contacted to the primer. In some cases a primer 10 can be contacted directly to seal 2 (as shown in FIG. 1), or to a surface of cover plate 3, as best suited to the desired application.

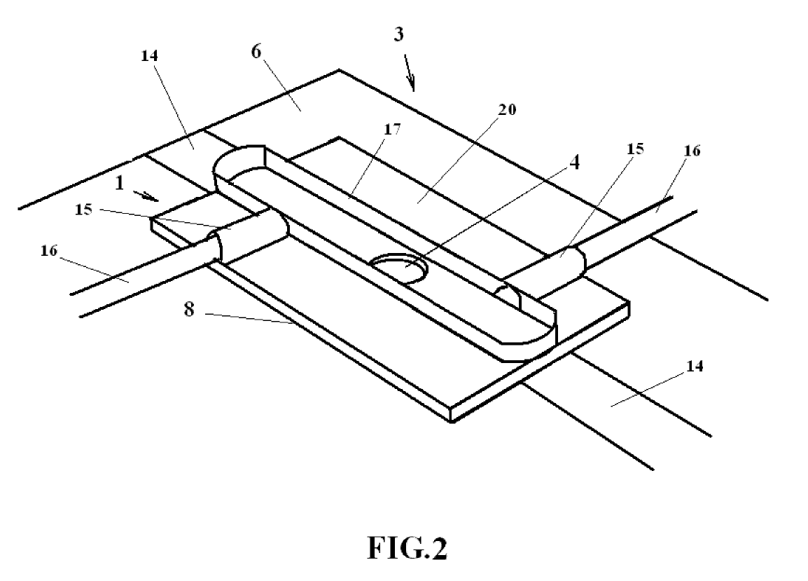

Referring to FIG. 2, cord plate 1 is positioned adjacent to cover plate 3, with seal 2 (FIG. 1) optionally positioned between cord plate 1 and cover plate 3. Cord plate 1 is positioned such that channel 4 is positioned over, and in fluid communication with, connector 5 (not shown). For example, channel 4 and connector 5 can include holes of similar diameter, in which case the hole included in channel 4 can be positioned directly over the congruous connector 5 hole. Channel 4 can also be positioned partially, but not completely, over connector 5.

In continuing reference to FIG. 2, when cord plate 1 is positioned adjacent to first surface 6 of cover plate 3, a space is defined by cover plate 3, connector 5 and portions of cord plate 1, including bottom surface 22 (whether recessed or not) and channel 4 (including partition 17 and the portion of top surface 20 included in the partition included in channel 4, if any). This space is in fluid communication, and can include additional space defined by opening 13 of seal 2, if seal 2 is included in the assembly.

As shown in FIG. 2, cord plate 1 includes junction 15, which can be a receptacle formed on top surface 22 of cord plate 1 and configured to position and intersect a second conductor 16 with conductor 14. Second conductor can include insulated electrical wiring for carrying electrons either to or from conductor 14, depending on whether junction 15 is a “positive” junction or a “negative” junction (cord plate 1 can include each type of junction). As shown in FIG. 2, junction 15 can be used to position and secure second conductor 16 proximate to conductor 14. After they are correctly positioned, conductor 14 and second conductor 16 can be connected, for example, by soldering. Second conductor 16 can be positioned in junction 15 either before or after cord plate 1 is positioned adjacent to first surface 6 of cover plate 3.

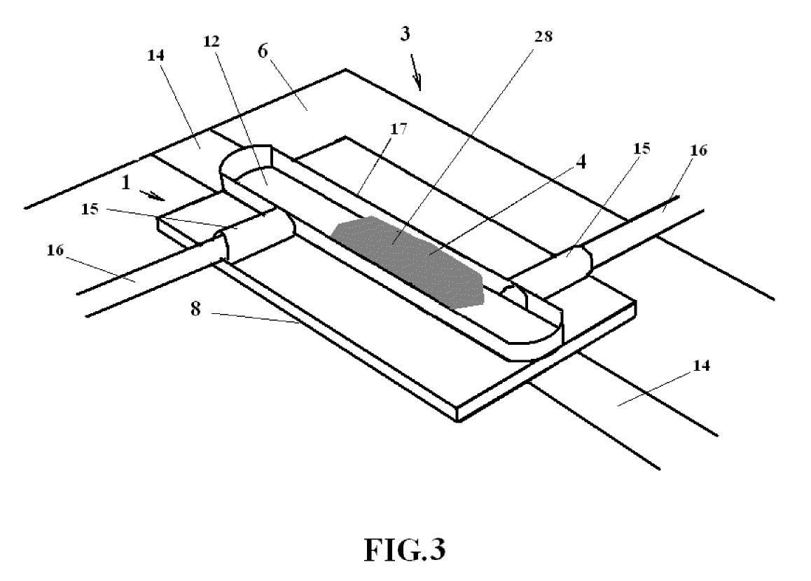

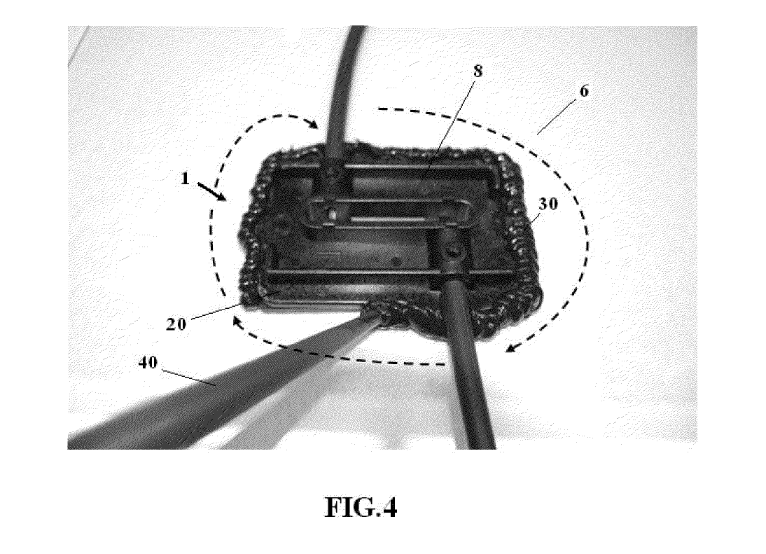

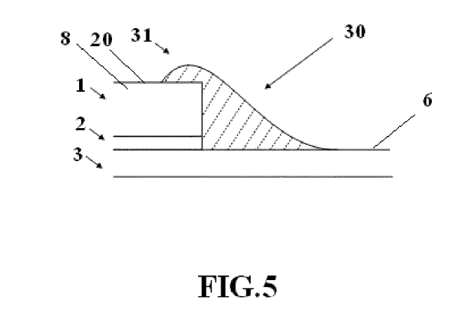

Referring to FIG. 3, flowable sealant 28 is introduced into and received by channel 4 and components thereof, including compartment 12 defined by partition 17 and the portion of top surface 20 contained therein, and the underlying hole formed in base 8 (not shown). Flowable sealant 28 can be any suitable sealant, including a low-viscosity sealant. Flowable sealant 28 can be a one-component sealant, a two-component sealant, or higher-component sealant. Flowable sealant can include any suitable substance, including silicone, acrylic, polysulfide, a butyl sealant, a one part or two part polyurethane sealant, or any other sealant capable of robustly sealing cord plate 1 to cover plate 3.

Flowable sealant 28 flows through channel 4 into the space defined by the bottom surface 22 of cord plate 1, cover plate 3, connector 5 and seal 2 (if present). In this manner, flowable sealant 28 contacts channel 4, cover plate 3 and connector 5 and any other component in fluid communication with channel 4 into which flowable sealant 28 has been introduced. Flowable sealant 28 can then cure to engage and adhere cord plate 1 and cover plate 3 and potentially other components flowable sealant contacts.

A number of embodiments of the invention have been described. Nevertheless, it will be understood that various modifications may be made without departing from the spirit and scope of the invention. It should also be understood that the appended drawings are not necessarily to scale, presenting a somewhat simplified representation of various preferred features illustrative of the basic principles of the invention.

1. A method of attaching a cord plate to a photovoltaic module having a cover plate comprising:
positioning a conductor adjacent to a cover plate of a photovoltaic device, the conductor comprising a first end configured to be connected to the photovoltaic device and a second end located proximate to a connector on a first surface of the cover plate;
positioning the cord plate on the first surface of the cover plate over the connector to form a space defined by the cover plate, the connector, and the cord plate, the cord plate comprising a base having a top surface and bottom surface and configured to be sealed to the cover plate, a junction configured to intersect the conductor and a second conductor, and a channel configured to receive a flowable sealant; and
positioning an acrylic foam sheet between the bottom surface of the cord plate and the first surface of the cover plate.

2. The method of claim 1, further comprising the steps of:
introducing a flowable sealant into the cord plate channel;
causing the flowable sealant to flow into the defined space and contact the channel, the cover plate and the connector; and
curing the flowable sealant to connect the cord plate to the cover plate.

3. The method of claim 1, wherein the cover plate comprises glass.

4. The method of claim 1, wherein the connector comprises an impression formed in the first surface of the cover plate.

5. The method of claim 1, wherein the connector comprises a hole formed through the cover plate.

6. The method of claim 1, wherein the conductor comprises a foil strip.

7. The method of claim 1, wherein the cord plate comprises plastic.

8. The method of claim 1, wherein the base comprises a rectangular plate.

9. The method of claim 1, wherein the base comprises a recess formed in the bottom surface.

10. The method of claim 1, wherein the junction comprises a receptacle formed on the top surface of the base and configured to position the second conductor in contact with the conductor.

11. The method of claim 10, further comprising electrically connecting the conductor and second conductor.

12. The method of claim 1, wherein the channel comprises an opening in the base.

13. The method of claim 1, further comprising the step of milling an opening in the base of the channel.

14. The method of claim 12, wherein the channel comprises a partition extending perpendicular from a surface of the base and encircling the opening.

15. The method of claim 1, wherein the second conductor comprises insulated electrical wiring configured to carry electrons either to or from the conductor.

16. The method of claim 1, wherein the flowable sealant comprises a silicone, an acrylic, a polysulfide, a butyl polymer, or a polyurethane.

17. The method of claim 1, further comprising the step of priming the bottom surface of the base before positioning on the cover plate.

18. The method of claim 17, wherein the bottom surface of the base is primed with a liquid primer.

19. The method of claim 17, wherein the bottom surface of the base is primed with flame treatment.

20. The method of claim 1, further comprising the step of positioning a seal on the first surface of the cover plate over the connector before positioning the cord plate on the first surface of the cover plate over the connector.

21. The method of claim 20, wherein the seal comprises an acrylic foam core.

22. The method of claim 21, wherein the seal comprises a pressure sensitive adhesive on a surface of the acrylic foam core.

23. A photovoltaic module comprising:
a photovoltaic device;
a cover plate positioned adjacent to the photovoltaic device, wherein the cover plate comprises a connector formed on a first surface of the cover plate;
a conductor comprising a first end connected to the photovoltaic device and a second end located proximate to the connector;
a cord plate comprising a base comprising a top surface and bottom surface and configured to be sealed to the cover plate, a junction configured to intersect the conductor and a second conductor, and a channel configured to receive a flowable sealant, wherein the cord plate is positioned on the first surface of the cover plate, over the connector, to form a space defined by the cover plate, the connector and the cord plate; and
an acrylic foam sheet positioned between the bottom surface of the cord place and the first surface of the cover plate.

24. The photovoltaic module of claim 23, further comprising a sealant introduced into the cord plate channel, the sealant contacting the channel, the cover plate and the connector.

25. The photovoltaic module of claim 23, further comprising a primer contacting the acrylic foam sheet.

26. The photovoltaic module of claim 25, wherein the primer comprises a water based primer.

27. The photovoltaic module of claim 25, wherein the primer comprises a compound which fluoresces when ultraviolet light is directed at the compound.

28. The photovoltaic module of claim 23, further comprising a pressure sensitive adhesive on a surface of the acrylic foam sheet.
